(19) United States
(12) Patent Application Publication
(10) Pub. No.: US 2003/0008229 A1
(43) Pub. Date: Jan. 9, 2003

(54) Thermally sensitive coating compositions useful for lithographic elements

(76) Inventors: Prakash Seth, Jackson, TN (US); Charles S. Cusumano, Boca Raton, FL (US)

Correspondence Address: PERMAN & GREEN, 425 POST ROAD, FAIRFIELD, CT, 06824, US

(21) Appl. No.: 09/891,081

(22) Filed: Jun. 25, 2001

(51) Int. Cl. G03F 7/004; G03F 7/038; G03F 7/039

(52) U.S. Cl. 430/270.1; 430/281.1; 430/302; 430/306; 430/325

(57) ABSTRACT

A photothermally sensitive composition which is primarily energy sensitive in the near infrared and ultraviolet region of the electromagnetic spectrum is composed of a novolak polymer, a melamine derivative crosslinking compound, an acid-generating compound, a polymeric dissolution inhibitor and an infrared absorbing dye. When applied to the proper support and processed, the composition is useful as an offset lithographic printing plate, color proofing film or image resist.

### BACKGROUND OF THE INVENTION

1. Field of the Invention

The invention relates to thermally sensitive coating compositions useful for the preparation of lithographic printing plates, color proofing films and the like.

2. Description of Related Art

The art of lithographic printing is based upon the immiscibility of oil and water, wherein the oily material or ink is preferentially retained by the image area and the water or fountain solution is preferentially retained by the non-image area. When a suitably prepared surface is moistened with water and an ink is then applied, the background or non-image area retains the water and repels the ink while the image area accepts the ink and repels the water. The ink on the image area is then transferred to the surface of a material upon which the image is to be reproduced, such as paper, cloth and the like. Commonly the ink is transferred to an intermediate material called the blanket which in turn transfers the ink to the surface of the material upon which the image is to be reproduced.

A very widely used type of lithographic printing plate has a light-sensitive coating applied to an aluminum base support. The coating may respond to light by having the portion which is exposed become soluble so that it is removed in the developing process. Such as a plate is referred to as positive-working. Conversely, when that portion of the coating which is exposed becomes hardened, the plate is referred to as negative-working. In both instances the image area remaining is ink-receptive or oleophilic and the non-image area or background is water-receptive or hydrophilic. The differentiation between image and non-image areas is made in the exposure process where a film is applied to the plate with a vacuum to insure good contact. The plate is then exposed to a light source, a portion of which is composed of UV radiation. In the instance where a positive plate is used, the area on the film that corresponds to the image on the plate is opaque so that no light will strike the plate, whereas the area on the film that corresponds to the non-image area is clear and permits the transmission of light to the coating which then becomes more soluble and is removed. In the case of a negative plate the converse is true. The area on the film corresponding to the image area is clear while the non-image area is opaque. The coating under the clear area of film is hardened by the action of light while the area not struck by light is removed. The light-hardened surface of a negative plate is therefore oleophilic and will accept ink while the non-image area which has had the coating removed through he action of a developer is desensitized and is therefore hydrophilic.

Direct digital imaging of offset printing plates has become increasingly important in the printing industry. Advances in solid-state laser technology have made medium to high-powered diode lasers attractive energy sources for platesetters, particularly lasers emitting energy in the near infrared (800-850 mm) regions. The use of controlled laser exposure obviates the need to use a film or mask when making image exposures, thereby facilitating a plate-making operation.

There are a number of United States patents relating to imaging compositions which are sensitive to infrared energy and which contain one or a mixture of phenolic resins and at least one infra-red absorbing dye or pigment. Positive acting plates based on a mixture of a novolac or resole or polyhydroxy-styrene resin and an IR absorbing dye are disclosed in U.S. Pat. No. 6,063,544. Printing plates based on a mixture of a novolak resin, a resole resin, an infrared absorbing dye or pigment and a latent Bronstead acid are disclosed in U.S. Pat. Nos. 5,372,907, 5,340,699, 5372915, 5466577, and 5491046. Exposure of these plates to infrared radiation decomposes the latent Bronstead acid to yield species which will serve to crosslink the resole and novolak resins, thereby hardening the mixture in the exposed areas. Further heating of the exposed plate tends to further harden the exposed coating which becomes insoluble in aqueous alkaline developer, while the non-exposed areas remain soluble in developer solution.

U.S. Pat. No. 5,663,037 contains similar disclosure, except that a haloakyl-substituted S-trazine is used as the decomposable IR sensitive material.

In addition, U.S. Pat. No. 5,919,601 discloses a radiation sensitive composition based on a mixture of a binder resin, a crosslinking resin, a thermal-active acid generator and an infrared absorber such that decomposition of the acid generator after exposure to infrared energy causes the release of an acid which in turn causes the crosslinking of the binder resin by the crosslinking agent.

One of the problems associated with these and similar systems is that there is often insufficient integrity of the image areas remaining after development of the printing plate to effectively perform the printing process over long printing runs, resulting in print images having less than desired resolution and print quality.

### SUMMARY OF THE INVENTION

The invention provides a radiation sensitive composition useful for the preparation of an imaging layer on a support which is capable of functioning in either a positive-working or negative-working manner, said composition comprising a mixture of: (a) a novolac resin, (b) a crosslinking agent for said resin comprising a melamine derivative, (c) a thermochemical acid-generating compound which generates a Bronstead acid when subjected to infrared irradiation; (d) a polymeric dissolution inhibitor and (e) an infrared radiation absorbing compound.

The invention also provides a process for preparing an image comprising (i) providing an imaging layer coated on a support material, said imaging layer comprising a mixture of (a) a novolac resin, (b) a crosslinking agent for said resin comprising a melamine derivative, (c) a thermochemical acid-generating compound which generates a Bronstead acid when subjected to infrared irradiation; (d) a polymeric dissolution inhibitor and (e) an infrared radiation absorbing compound, ii) imagewise exposing said imaging area to an energy source emitting an infrared laser beam of sufficient energy to at least partially decompose said thermochemical acid-generating compound to form an exposed latent image, and iii) contacting said image area with developer material wherein the exposed areas of said imaging layer are selectively removed from said support.

The invention further provides a process for preparing an image comprising i) providing an imaging layer coated on a support material, said imaging layer comprising a mixture of (a) a novolac resin, (b) a crosslinking agent for said resin comprising a melamine derivative, (c) a thermochemical acid-generating compound which generates a Bronstead acid when subjected to infrared irradiation; (d) a polymeric dissolution inhibitor and (e) an infrared radiation absorbing compound, ii) imagewise exposing said imaging area to an energy source emitting an infrared laser beam of sufficient energy to at least partially decompose said thermochemical acid-generating compound to form an exposed latent image, iii) heating said exposed latent image on said support at a temperature of at least about 80° C. sufficient to crosslink said novolak resin in image areas exposed to said energy; iv) and contacting said image area with development material wherein the nonexposed areas of said imaging layer are selectively removed from said support.

The radiation sensitive compositions of this invention may be applied to various substrates to form photosensitive elements. If applied to a textured and anodized aluminum plate, the coated plate may be used as a planographic (lithographic) printing plate capable of printing thousands of high quality, high resolution images. If the composition is applied to a transparent film support, eg, a polyester film, it may be advantageously used as a film for color proofing. The composition may also be used as a photoresist for making printed circuits.

### DETAILED DESCRIPTION OF THE INVENTION

The novolak resin used in the present invention is the condensation product of a phenolic or an aliphatic substituted hydroxy aromatic compound and an aldehyde. Preferred novolak resins include a condensation product of phenol, o-chlorophenol, o, m or p-cresol, p-hydroxy benzoic acid, 2-naphthol or other hydroxy aromatic monomers with an aldehyde such as formaldehyde, acetaldehyde, fural, benzaldehyde, or any other aliphatic or aromatic aldehyde. This polymer is preferred to have a molecular weight in the range or 1000 to 70,000, more preferred in the range of 2,000 to 40,000, and most preferred in the range of 3,000 to 12,000. Novolaks are common materials readily available commercially. Due to how they are prepared, there is a variability that will exist from lot-to-lot that makes the coating vary too much to be considered a reliable product. High and low molecular weight polymers are advantageously blended to insure a constant product. The intrinsic viscosity is measured using a Pensky Marten capillary method. 10.0% (w/w) is dissolved in methylethyl ketone. A # 300 capillary tube is immersed in a water bath maintained at 25° C. Using the constant for the tube times the seconds measured, the viscosity in centistokes is obtained. The preferred range is 2-50 centistokes. More preferred is 3-35 centistokes. Most preferred is 4-20 centistokes. By measuring the viscosity of two novolaks having different molecular weights, variations can be obviated by changing the ratios to achieve the target viscosity.

The crosslinking compound used in the composition may be broadly described as a melamine derivative, more specifically a derivative selected from the group consisting of C₁ to C₅ alkoxy methyl melamines or imino melamines, C₁ to C₅ alkanol melamines or imino melamines, mixed C₁ to C5 alkoxy methyl 3/C₁ to C₅ alkanol melamines or imino melamines and mixtures thereof. Preferred melamine derivatives include but are not restricted to hexamethoxymethyl melamine, trimethylol melamine, hexamethylol melamine, trimethoxymethyl imino melamine, trimethylol imino melamine, tributoxymethyl imino melamine, trimethyloltrimethoxymethyl melamine, tributoxymethyl trimethoxymethyl melamine, and mixtures thereof.

The infrared absorber used in the invention is a compound which will absorb radiation in the IR range of about 750 to 875 nm, more preferably in the range of about 800 to 850 nm and most preferably at about 830 nm. Classes of materials which are useful include but are not limited to squarlium, cyanide, polymethine, and pyrilium dyes or pigments, although dyes are preferred. Preferred dyes include, but are not limited to pyridyl, quinolinyl, benzoxazolyl, thiazolyl, benzothiazolyl, oxazolyl and selenazolyl. The optimal dye must be selected with care so that the absorption (lambda maximum) is closely matched with the output wavelength of the laser used for exposure. Dyes advantageously will enhance the differentiation between the image and non-image areas created when the laser images the medium being employed.

The coating composition also contains a fourth component which is a polymeric dissolution inhibitor. The function of this material is to inhibit dissolution or erosion of the image areas during development while not interfering with the other performance characteristics of the coatings such as to allow facile processing of the non-image areas of a plate. Suitable polymers are those containing acid or acid derivative groups such as copolymers of styrene with maleic acid, maleic anhydride or maleic acid half ester; cellulose acetate butyrate; cellulose acetate propionate; polyvinyl acetate; maleic acid or maleic anhydride derivatives of polyvinyl methyl ether, and mixtures thereof.

The fifth essential component in the composition includes a latent Bronstead acid. The term “Latent Bronstead acid” refers to a precursor which generates a Bronstead acid when exposed to heat or light energy in the infrared region of the spectrum. The resulting Bronstead acid either catalyzes the crosslinking reaction between the novolak and melamine derivative in the exposed areas where negative working systems are used, or assists in the photo decomposition of the polymers in the exposed areas where positive-working systems are used. Preferred materials are those which release a Bronstead acid upon exposure to heat generated by infrared or near-infrared radiation using an IR laser.

Representative compounds of various classes of thermochemical Bronstead acid generating compounds are described, for example, in U.S. Pat. No. 5,466,557, incorporated herein by reference.

Particularly useful compounds include halogenated compounds such as halogenated triazines (or S-triazine derivatives), halogenated 2-pyrones, halogenated oxazoles, halogenated oxadiazoles, and halogenated thiazoles. Generally, such compounds have polyhalomethyl groups such as trihalomethyl groups that can generate the desired hydrohalic acid upon heating from infrared irradiation.

The most preferred acid generators are advantageously selected from the various trichloromethyltriazines. These include, but are not restricted to: tris-trichloro methyl triazine, bis-trichloromethyl phenyl triazine, bis-trichloromethyl o- or p-methoxyphenyl triazine, bis-trichloromethyl (3,5-dimethoxy) phenyl triazine, bis-trichloromethyl naphthyl triazine, bis-trichloromethyl 5-methoxynaphthyl triazine, bis-trichloromethyl styryl triazine, and bis-trichloromethyl (4-methoxy) styryl triazine.

The composition also may include a colorant (indicator dye) which aids in visual identification of image areas after development of a printing plate. The composition may also contain any of the known cyan, yellow or magenta dyes or pigments for use in color proofing applications. Preferred colorants include Victoria Blue, Basic Blue, methylene blue, crystal violet, Disperse Red 1,4, or 13, and methyl violet.

The composition may also include other additives normally used in photothermal sensitive compositions such as surfactants, acid stabilizers and wetting agents.

The composition is coated onto a support by first forming a solution in suitable organic solvent and applying the solution to a substrate support such as an anodized aluminum plate or polyester film. Coating methods include conventional roll, gravure, spin or hopper coating processes. Suitable coating solvents include, but are not restricted to: 1-methoxy-2-ethanol, 1-methoxy-2-propanol, acetone, methyl ethyl ketone, diisobutyl ketone, methyl isobutyl ketone, n-propanol, isopropanol, tetrahydrofuran, butyrolactone, methyl lactate, and mixtures thereof.

The coating components are dissolved in the desired solvent system. The coating solution is applied to the substrate of choice. The coating is applied so as to have a dry coating weight in the range or about 0.8 g/M² to about 3.5 g/M². More preferred is from about 1.1 g/M² to about 2.7 g/M², and most preferred is from about 1.3 g/M² to about 2.4 g/M². The coating is dried under conditions that will effectively remove all solvent, but not so aggressive as to cause any degradation of the acid generator or laser dye or reaction of the polymers with themselves or with each other. It is essential that energy transfer mechanisms not be initiated during the drying of the coating which would result in image formation which would in turn result in a background which would be difficult to desensitize.

As indicated above, the radiation heat sensitive composition may be used in computer-to-plate image technology. Because of the versatility of these compositions, they may be used in “write the image” or “write the background” approaches to plate exposure. In the case of “write the image” version, the portion of the coating struck with energy becomes the image, such as in a negative working system. After laser exposure, the plate is heated to finish the crosslinking process. It is then developed using suitable alkaline aqueous developer and prepared for press. In the case of “write the background” version, the portion of the coating struck with energy is removed during the development process and the remaining image area becomes the background. In this instance no pre-heating prior to development takes place. The relative proportions of the Novolak resin and the melamine derivative present in the composition determine the system chemistry.

For the “write-the-image” approach, the novolak resin is preferably used in the range from about 50% to about 95%. More preferred is from about 55% to about 85% and most preferred about 60 to about 75%. The melamine derivative is preferably used in the range from about 2% to about 35%. More preferred is about 4% to about 25%, and most preferred is from about 6% to about 18%. The infrared absorbing medium is preferably used in the range from about 0.5% to about 12%. More preferred is from about 1% to about 10%, and most preferred is from about 2% to about 7%. The photoacid generator is preferably used in the range of from about 0.5 to about 12%, more preferably from about 1 to about 10% and most preferably about 2 to about 7%. The dissolution inhibitor is preferably used in the range from about 1% to about 20%. More preferred is from about 3% to about 15%, and most preferred is from about 5% to about 10%.

For the “write-the-background” approach, the novolak resin is preferably used in the range from about 5% to about 40%. More preferred is from about 10% to about 35% and most preferred is from about 15% to about 30%. The melamine derivative is preferably used in the range from about 40% to about 90%. More preferred is from about 45% to about 80%, and most preferred is from about 50% to about 70%. The infrared absorbing medium is preferably used in the range from about 0.5% to about 12%. More preferred is from about 1% to about 10%, and most preferred is from about 2% to about 7%. The photoacid generator is preferably used in the range from about 1% to about 15%. More preferred is from about 2% to about 12%, and most preferred is from about 4% to about 10%. The dissolution inhibitor is preferably used in the range from about 1% to about 20%. More preferred is from about 3% to about 15%, and most preferred is from about 5% to about 10%. All weights described above are based on the dry weight of the coating composition. When used as a printing plate, the composition is primarily sensitive to energy in the infrared region. There is also sensitivity in the ultraviolet region of the spectrum depending upon the nature of the acid generator present in the composition. This dual sensitivity can afford the advantage of imaging with a laser imagesetter or with convention contact exposure.

A plate is preferably placed on an imagesetter for imaging. Image setters may output at a variety of wavelengths in the UV, visible and infrared portions of the electromagnetic spectrum. Presently there is one wavelength predominantly used for infrared imaging. An array of laser diodes emitting at 830 nm is commercially available. The laser diode array is a series of diodes connected with fiber optics. The total power available can very from 1 to 14 watts and is applied for an amount of time to yield available energy for imaging of up to 250 mJ./cm². The preferred energy ranges from about 130 to 210 mJ./cm². A suitable imaging device is manufactured and sold by Creo-Scitex, Vancouver, Canada. Digitized information is used to modulate the output from the laser. The energy is directed to the plate surface where an energy transfer mechanism occurs. The absorbing dye absorbs the energy and emits the energy as intense localized heat. The heat in turn causes the degradation of the acid generator, which results in the release of a strong acid. The acid in turn causes a reaction to occur with the polymers and crosslinking compound. The reaction occurs in what will become the image when a heating step is applied after imaging. In convention terms this would be a negative plate or “write-the-image” mode. Here the area struck with energy becomes the image while the balance of the coating is removed in the developing process. When the heating step is eliminated, the imaged area becomes the background. The imaging reaction causes a photosolubilization, which is a “write-the-background” approach. Here the portion of the coating struck with energy is removed in the developing process, and the unaffected area becomes the image.

Depending upon the specific composition, the energy provided by the laser may be sufficient to adequately initiate the reaction and take it to completion. In instances when it is not sufficient, additional energy is required, which is typically applied in the form of a pre-heat step. This is accomplished by running the plate through an oven after being imaged and prior to being developed. The temperature is typically in the range of 80 to 140° C. A most common temperature is about 120° C. The time required at this temperature is between 30 and 120 seconds. Most commonly, about 1 minute is required.

All coating compositions described are developed using a developer composition, which is completely aqueous and has a high pH. Developers typically used for positive plates are most useful. The developer takes advantage of the differentiation created with the exposure to remove the background coating and permit the image to remain. At this point the image is capable of some performance on press, particularly if the required number of impressions is low. For extended performance, the coating may be baked after development. The baking step completes the cross-linking of the polymers and results in an image capable providing may thousands more images than without baking. The baking temperature range is from about 180° C. to 260° C. Most commonly 230° C. is used. The time ranges from 1 to 10 minutes. Most commonly 3-5 minutes is used. Baking is usually performed with a conveyor oven such as those sold by Wisconsin Oven.

The following examples are illustrative of the invention:

### EXAMPLE 1

A coating solution was prepared by dissolving 5.74 gr. Of Novolak HRJ 2606 (a novolak resin sold by Schenectady), 0.57 of Cymel 300 (a polymethylol resin sold by Cytec), 0.98 gr of cellulose acetate butyrate (CAB 321-0.1 sold by Eastman Chemicals), 0.19 gr. of infrared absorbent dye (laser dye 830AT sold by ADS, Montreal, Canada), 0.47 gr of p-methoxyphenyl bis(trichloromethyl) triazine, and 0.05 gr of Victoria Blue in 92.0 gr of 1-methoxy-2-propanol. An aluminum substrate that had been degreased, mechanically grained, anodized and made hydrophilic with a treatment of polyvinyl phosphonic acid, as is well known to one skilled in the art, was coated with the above composition. The dry coating weight was 1.7 g/m2. When properly dried, the plate was placed in a Creo-Scitex Trendsetter imagesetter. Imaging was done in the “write-the-image” mode using 200 mJ./cm2 of energy at 830 nm. The plate was then run through a Wisconsin oven set at 120° C. and with a dwell time of 60 seconds. The plate was developed through a processing machine, which was charged with conventional positive developer. The developed plate was observed to have a very strong positive image with good resolution. Based upon a resolution target, the microlines were 6/8 and the halftone dot resolution was 2-98. Under accelerated wear press conditions the plate produced 12,000 impressions before it was considered unacceptable for commercial quality.

### EXAMPLE 2

In like manner as described in example 1, a plate was similarly prepared except that the cellulose acetate butyrate was eliminated. An aluminum plate heretofore described was coated and imaged using 200 mJ/cm2. The plate was then run through a Wisconsin oven set at 120° C. and with a dwell time of 60 seconds. The plate was developed through a processing machine, which was charged with conventional positive developer. The plate had microline resolution of 6/8 and halftone resolution of 2-98. When run on press only 3,500 acceptable impressions were obtained before considering the quality commercially unacceptable. This test shows that although the image appeared acceptable before placing the plate on press, the image integrity was compromised through the development process. Therefore the utility of the dissolution inhibitor is exemplified.

### EXAMPLE 3

In like manner as described in example 1, a plate was similarly prepared except that the Cymel 300 was eliminated. An aluminum plate heretofore described was coated and imaged using 200 mJ/cm2. The plate was then run through a Wisconsin oven set at 120° C. and with a dwell time of 60 seconds. The plate was developed through a processing machine, which was charged with conventional positive developer. The image of the plate was very weak after processing. Most of the coating in the image area was removed. It was not seen as acceptable for press evaluation. This test shows the how essential the cross-linking agent is for producing an acceptable image with good resolution and image integrity.

### EXAMPLE 4

In like manner as described in example 1, a plate was similarly prepared except that the p-methoxyphenyl bis(trichloromethyl) triazine was eliminated. An aluminum plate heretofore described was coated and imaged using 200 mJ/cm2. The plate was then run through a Wisconsin oven set at 120° C. and with a dwell time of 60 seconds. The plate was developed through a processing machine, which was charged with conventional positive developer. Upon inspection the plate was observed to have no image. This test shows how essential the acid generator is for good image formation.

### EXAMPLE 5

In like manner as described in example 1, a plate was similarly prepared except that the 830AT laser dye was eliminated. An aluminum plate heretofore described was coated, imaged using 200 mJ/cm2. The plate was then run through a Wisconsin oven set at 120° C. and with a dwell time of 60 seconds. The plate was developed through a processing machine, which was charged with conventional positive developer. A visible image was seen on the plate before processing. After processing there was a faint image remaining on the plate. It was considered insufficient for running on the press.

### EXAMPLE 6

In like manner as described in example 1, a plate was similarly prepared except that 4-methoxy styryl bis(trichloromethyl) triazine was substituted for the p-methoxyphenyl bis(trichloromethyl) triazine. An aluminum plate heretofore described was coated and imaged using 200 mJ/cm2. The plate was then run through a Wisconsin oven set at 120° C. and with a dwell time of 60 seconds. The plate was developed through a processing machine, which was charged with conventional positive developer. Based upon a resolution target, the microlines were 6/8 and the halftone dot resolution was 2-98. Under accelerated wear press conditions the plate produced 10,000 impressions before it was considered unacceptable for commercial quality. Here it is shown that there was nothing unique about the particular triazine selected. A wide variety of analogous compounds would be expected to function comparably.

### EXAMPLE 7

In like manner as described in example 1, a plate was similarly prepared except that the cellulose acetate butyrate was substituted with Scriptset 540 (esterified styrene/maleic anhydride copolymer). An aluminum plate heretofore described was coated and imaged using 200 mJ/cm2. The plate was then run through a Wisconsin oven set at 120° C. and with a dwell time of 60 seconds. The plate was developed through a processing machine, which was charged with conventional positive developer. The plate had microline resolution of 6/8 and halftone resolution of 2-98. Under accelerated wear press conditions the plate produced 12,500 impressions before it was considered unacceptable for commercial quality. Here it is shown that there was nothing unique about the particular polymer selected as the dissolution inhibitor. A wide variety of analogous compounds would be expected to function comparably.

### EXAMPLE 8

In like manner as described in example 1, a plate was similarly prepared except that the Cymel 370 was substituted for the Cymel 300 (Cymel 370 is a polymethoxymethyl-methylol melamine as compared to Cymel 300 which is hexamethoxymethyl melamine). An aluminum plate heretofore described was coated and imaged using 200 mJ/cm2. The plate was then run through a Wisconsin oven set at 120° C. and with a dwell time of 60 seconds. The plate was developed through a processing machine, which was charged with conventional positive developer. The developed plate was observed to have a very strong positive image with good resolution. Based upon a resolution target, the microlines were 6/8 and the halftone dot resolution was 2-98. Under accelerated wear press conditions the plate produced 11,000 impressions before it was considered unacceptable for commercial quality. Here it is shown that there was nothing unique about the particular monomer selected as the cross-linking agent. A wide variety of analogous compounds would be expected to function comparably.

### EXAMPLE 9

A coating solution was prepared by dissolving 6.16 gr. of Rutaphen 0744 (a novolak resin sold by Bakelite AG), 0.57 of Cymel 1158 (a n-butylated high imino melamine resin sold by Cytec), 0.80 gr of cellulose acetate butyrate (CAB 553-0.4 sold by Eastman Chemicals), 0.28 gr. of laser dye Epolite VI-148 sold by Epolin, Inc., Newark, N.J.), 0.24 gr of tris(trichloromethyl) triazine, and 0.04 gr of methylene blue in 92.0 gr of 1-methoxy-2-propanol. An aluminum substrate that had been degreased, mechanically grained, anodized and made hydrophilic with a treatment of polyvinyl phosphonic acid, as is well known to one skilled in the art, was coated with the above composition. The dry coating weight was approximately 1.6 g/M2. When properly dried, the plate was placed in a Creo-Scitex Trendsetter imagesetter. Imaging was done in the “write-the-image” mode using 200 mJ/cm2 of energy at 830 nm. The plate was then run through a Wisconsin oven set at 120° C. and with a dwell time of 60 seconds. The plate was developed through a processing machine, which was charged with conventional positive developer. The developed plate was observed to have a very strong positive image with good resolution. Based upon a resolution target, the microlines were 6/8 and the halftone dot resolution was 1-98. Under accelerated wear press conditions the plate produced 11,700 impressions before it was considered unacceptable for commercial quality. This evaluation shows that a completely different composition with changed ratios, within the specified ranges, yields acceptable performance.

### EXAMPLE 10

A coating solution was prepared by dissolving 5.67 gr. of Durite PD-140A (a novolak resin sold by Borden Chemical, Inc.), 0.54 of Cymel 303 (hexamethoxymethylmelamine resin sold by Cytec), 0.58 gr of Scripset 540 (esterified styrene maleic anhydride copolymer), 0.18 gr. of laser dye 830 AT, 0.56 gr of tris(trichloromethyl) triazine, and 0.06 gr of Victoria Blue in 92.0 gr of 1-methoxy-2-propanol. An aluminum substrate that had been degreased, mechanically grained, anodized and made hydrophilic with a treatment of polyvinyl phosphonic acid, as is well known to one skilled in the art, was coated with the above composition. The dry coating weight was approximately 1.7 g/M2. When properly dried, the plate was placed in a Creo-Scitex Trendsetter imagesetter. Imaging was done in the “write-the-image” mode using 180 mJ/cm2 of energy at 830 nm. The plate was then run through a Wisconsin oven set at 1200 C and with a dwell time of 60 seconds. The plate was developed through a processing machine, which was charged with conventional positive developer. The developed plate was observed to have a very strong positive image with good resolution. Based upon a resolution target, the microlines were 4/6 and the halftone dot resolution was 1-98. Under accelerated wear press conditions the plate produced 12,700 impressions before it was considered unacceptable for commercial quality. This evaluation shows that a completely different composition with changed ratios, within the specified ranges, yields acceptable performance.

### EXAMPLE 11

In like manner as described in Example 10, the same coating was prepared on a plate and evaluated using combinations of different times and energies for pre-heating the plate. All of the experiments were conducted isothermally at 115° C.

| ENERGY | Time(sec) | | | | | | | |
|---|---|---|---|---|---|---|---|---|
| (mJ/cm2) | 75 | 100 | 125 | 150 | 175 | 200 | 225 | 250 |
| 60 | NI | NI | WI | WI | GI | GI | GI | OI |
| 90 | NI | NI | WI | GI | GI | GI | OI | OI |
| 120 | NI | WI | WI | GI | GI | GI | OI | OI |
| 150 | WI | WI | GI | GI | GI | OI | OI | OI |
| 180 | WI | GI | OI | OI | OI | OI | OI | OI |

NI = no image formed; WI = weak image; GI = good image; OI = over imaged

This example shows the reciprocity between time and energy and that there is a wide window of operability. Typically background sensitivity becomes an issue if the time in the oven is too long. Here it can be seen that at or before 3 minutes (180 seconds), the window begins to narrow.

### EXAMPLE 12

In like manner as described in Example 11, the same coating was prepared on a plate and evaluated using combinations of different temperatures and energies for pre-heating the plate. All of the experiments were conducted with the same dwell time in the oven of 90 seconds.

| ENERGY | TEMP. (° C.) | | | | | | | |
|---|---|---|---|---|---|---|---|---|
| (mJ/cm2) | 75 | 100 | 125 | 150 | 175 | 200 | 225 | 250 |
| 90 | NI | NI | NI | NI | NI | WI | WI | GI |
| 100 | NI | NI | NI | NI | WI | WI | GI | GI |
| 110 | NI | NI | WI | WI | GI | GI | GI | OI |
| 120 | NI | WI | WI | GI | GI | GI | GI | OI |
| 130 | WI | WI | GI | GI | GI | GI | OI | OI |

NI = no image formed; WI = weak image; GI = GOOD IMAGE; OI = over imaged

This example shows the reciprocity between temperature and energy and that there is a wide window of operability. Typically background sensitivity becomes an issue if the pre-heat temperature is too high. This is referred to as the fog point and is independent of the quality of the image formed. Fogging occurs when the coating components are cross-linking due to the thermal activation of the coating components. In this series, all backgrounds were clean up to 120° C. At to 130° C. the background was showing a very light blue stain although there was variability from unacceptable to acceptable in terms of the image.

### EXAMPLE 13

A Kodak Polychrome Graphics 2919 Thermal Plate was evaluated against the plate described in Example 10, wherein both were imaged, pre-heated and processed identically. The plate described in Example 10 required 150 mJ/cm2 to achieve the identical resolution achieved on the Kodak Polychrome plate using 155 mJ/cm2. Both were run on press under accelerated wear conditions both baked and unbaked (after development at 230° C. for 2 minutes). Both had comparable resolution at startup of 4/4 on microlines and 1-98 on halftones. Note: although each plate had better resolution, the press conditions caused he shadows to fill in. Both plates unbaked ran to about 12,000 impressions. The baked plates ran to about 27,000 at which point they were determined to be no longer acceptable for commercial print quality. This test suggests that the subject of this invention performs comparably to the recognized industry standard product now in the market.

### EXAMPLE 14

In like manner as described in Examples 1,9 and 10 plates were prepared. In the present instance, instead of imaging the plates with the laser image setter, they were contact exposed in a conventional vacuum frame using about 70 mJ/cm2 of broadband UV energy. All three plates imaged were preheated as described in the respective example and then developed. The plate resolution with contact exposure was not quite as good as those imaged with a laser, but was comparable to conventional positive plates. The performance on press was also comparable to the performance of the same plates imaged with IR energy. This shows the ability for these plates to be interchangeably used as a CTP product or a conventional plate.

What is claimed is:

1. A radiation sensitive composition useful for the preparation of an imaging layer on a support which is capable of functioning in either a positive-working or negative-working manner, said composition comprising a mixture of: (a) a novolak resin, (b) a crosslinking agent for said resin comprising a melamine derivative, (c) a thermochemical acid-generating compound which generates a Bronstead acid when subjected to infrared irradiation; (d) a polymeric dissolution inhibitor; and (e) an infrared radiation absorbing compound.

2. The composition of claim 1 wherein said novolak resin is a cresol-formaldehyde resin.

3. The composition of claim 1 wherein said acid-generating compound is a halogenated triazine.

4. The composition of claim 1 wherein said melamine derivative is selected from the group consisting of C₁ to C₅ alkoxy methyl melamines or imino melamines, C₁ to C₅ alkanol melamines or imino melamines, mixed C₁ to C₅ alkoxy methyl/C₁ to C₅ alkanol melamines or imino melamines and mixtures thereof.

5. The composition of claim 1 wherein said polymeric dissolution inhibitor is selected from the group consisting of copolymers of styrene with maleic acid, maleic anhydride or maleic acid half ester, cellulose acetate butyrate, cellulose acetate propionate, polyvinylacetate, maleic acid or maleic anhydride derivatives of polyvinyl methyl ether and mixtures thereof.

6. The composition of claim 1 wherein component (a) is present at a level of about 5-95 wt %, component (b) is present at a level of about 2-90 wt % component (c) is present at a level of about 0.5-15 wt %, component (d) is present at a level of about 1-20 wt. %, and component (e) is present at a level of about 0.5-12 wt %, each based on the dry weight of said composition.

7. The composition of claim 6 wherein component (a) is present at a level of about 5-40 wt % %, component (b) is present at a level of about 40-90 wt % and component (c) is present at a level of about 1-15 wt %.

8. The composition of claim 6 wherein component (a) is present at a level of about 50-95 wt %, component (b) is present at a level of about 2-35 wt %, and component (c) is present at a level of about 0.5-12 wt %.

9. The composition of claim 1 wherein said support comprises a printing plate.

10. The composition of claim 1 applied to a printing plate.

11. The composition of claim 10 where said printing plate is an aluminum sheet.

12. A process for preparing an image comprising:
i) providing an imaging layer coated on a support material, said imaging layer comprising the mixture of claim 7;
ii) imagewise exposing said imaging layer to energy emitting an infrared laser beam of sufficient energy to at least partially decompose said thermochemical acid-generating compound to form an exposed latent image; and
iii) contacting said image area with developer material wherein the exposed areas of said imaging layer are selectively removed from said support.

13. A process for preparing an image comprising:
i) providing an imaging layer coated on a support material, said imaging layer comprising the mixture of claim 8;
ii) imagewise exposing said imaging layer to energy emitting an infrared laser beam of sufficient energy to at least partially decompose said thermochemical acid generating compound to form an exposed latent image,
iii) heating said exposed latent image on said support at a temperature of at least about 80° C. sufficient to crosslink said novolak resin in image areas exposed to said light; and
iv) contacting said image area with developer material wherein the non-exposed areas of said imaging layer are selectively removed from said support.
